(19) United States
(12) Patent Application Publication
(10) Pub. No.: US 2024/0006560 A1
(43) Pub. Date: Jan. 4, 2024

(54) Electronic device and method for manufacturing the same

(71) Applicant: InnoLux Corporation, Miao-Li County (TW)

(72) Inventors: Ming-Chih TSAI, Miao-Li County (TW); Fan-Wei KUO, Miao-Li County (TW)

(21) Appl. No.: 18/325,641

(22) Filed: May 30, 2023

(30) Foreign Application Priority Data
Jun. 30, 2022 (CN) 202210776063.0
Aug. 3, 2022 (CN) 202210941325.4

(51) Int. Cl. H01L 33/38; H01L 33/58

(52) U.S. Cl. CPC H01L 33/382; H01L 33/58; H01L 2933/0058; H01L 2933/0016

(57) ABSTRACT

An electronic device is provided, which includes: a first substrate; a second substrate disposed opposite to the first substrate; a plurality of first electrodes disposed on the first substrate; an insulating layer disposed between the first substrate and the plurality of first electrodes; and a first spacer disposed between the first substrate and the second substrate, wherein the insulating layer has a first opening, the first opening includes a first enlarged part, and the first enlarged part and the first spacer are overlapped in a normal direction of the first substrate. A manufacturing method of the electronic device is also provided.

### CROSS-REFERENCE TO RELATED APPLICATIONS

This application claims the benefits of the Chinese Patent Application Serial Numbers 202210776063.0 and 202210941325.4, respectively filed on Jun. 30, 2022 and Aug. 3, 2022, the subject matter of which is incorporated herein by reference.

### BACKGROUND

### Field

The present disclosure provides an electronic device and a method for manufacturing the same. More specifically, the present disclosure provides an electronic device comprising an insulating layer with specific designs and a method for manufacturing the same.

### Description of Related Art

When the resistance of the electrodes in electronic products is too high, the high resistance may affect the conductivity of the electrodes. Generally, the resistance can be reduced by increasing the thickness of the conductive layer. However, when the thickness of the conductive layer increases, the problem of etching residue is easily to occur, which in turn leads to short circuits and other disadvantages.

Therefore, it is desirable to provide an electronic device to improve the conventional disadvantages.

### SUMMARY

The present disclosure provides an electronic device, comprising: a first substrate; a second substrate disposed opposite to the first substrate; a plurality of first electrodes disposed on the first substrate; an insulating layer disposed between the first substrate and the plurality of first electrodes; and a first spacer disposed between the first substrate and the second substrate, wherein the insulating layer has a first opening, the first opening comprises a first enlarged part, and the first enlarged part and the first spacer are overlapped in a normal direction of the first substrate.

The present disclosure also provides a method for manufacturing an electronic device, comprising the following steps: providing a first substrate; forming an insulating layer on the first substrate; forming a conductive layer on the insulating layer; patterning the insulating layer to make the insulating layer has a first opening; and patterning the conductive layer to form a plurality of first electrodes, wherein there is a first spacing area between two adjacent first electrodes of the plurality of first electrodes, and the first spacing area and the first opening are overlapped in a normal direction of the first substrate.

Other novel features of the disclosure will become more apparent from the following detailed description when taken in conjunction with the accompanying drawings.

### BRIEF DESCRIPTION OF DRAWINGS

FIG. 1 is a schematic view showing a method for manufacturing an electronic device according to one embodiment of the present disclosure.

FIG. 2 is a schematic view showing a method for manufacturing an electronic device according to one embodiment of the present disclosure.

FIG. 3A is a three-dimensional schematic view of a part of an electronic device according to one embodiment of the present disclosure.

FIG. 3B is a top view showing a part of a first substrate according to one embodiment of the present disclosure.

FIG. 3C is a bottom view showing a part of a second substrate according to one embodiment of the present disclosure.

FIG. 4 is a cross-sectional view of a part of an electronic device according to one embodiment of the present disclosure.

FIG. 5A to FIG. 5C are cross-sectional views of a part of an electronic device according to different embodiments of the present disclosure.

FIG. 6 is a chromaticity diagram according to one embodiment of the present disclosure.

### DETAILED DESCRIPTION

Reference will now be made in detail to exemplary embodiments of the present disclosure, examples of which are illustrated in the accompanying drawings. Wherever possible, the same reference numerals are used in the drawings and description to refer to the same or like parts.

Throughout the specification and the appended claims, certain terms may be used to refer to specific components. Those skilled in the art will understand that electronic device manufacturers may refer to the same components by different names. The present disclosure does not intend to distinguish between components that have the same function but have different names. In the following description and claims, terms such as “containing” and “comprising” are open-ended terms, and should be interpreted as meaning “including but not limited to . . . ”.

Directional terms mentioned in the specification, such as “up”, “down”, “front”, “rear”, “left”, “right”, etc., only refer to the directions of the drawings. Accordingly, the directional term used is for the purpose of illustration, not limitation, of the present disclosure. In the drawings, various figures illustrate the general characteristics of methods, structures and/or materials used in particular embodiments. However, these drawings should not be construed to define or limit the scope or nature encompassed by these embodiments. For example, the relative sizes, thicknesses and positions of various layers, regions and/or structures may be reduced or enlarged for clarity.

One structure (or layer, component, substrate) described in the present disclosure is disposed on/above another structure (or layer, component, substrate), which can mean that the two structures are adjacent and directly connected, or can refer to two structures that are adjacent rather than directly connected. Indirect connection means that there is at least one intermediate structure (or intermediate layer, intermediate component, intermediate substrate, intermediate space) between the two structures, the lower surface of one structure is adjacent to or directly connected to the upper surface of the intermediate structure, and the upper surface of the other structure is adjacent to or directly connected to the lower surface of the intermediate structure. The intermediate structure may be a single-layer or multi-layer physical structure or non-physical structure, which is not limited. In the present disclosure, when a certain structure is arranged “on” other structures, it may mean that a certain structure is “directly” on other structures, or it means that a certain structure is “indirectly” on other structures; that is, at least one structure is sandwiched, in between a certain structure and other structures.

The terms, such as “about”, “equal to”, “equal” or “same”, “substantially”, or “approximately”, are generally interpreted as within 20% of a given value or range, or as within 10%, 5%, 3%, 2%, 1%, or 0.5% of a given value or range.

Furthermore, any two values or directions used for comparison may have certain errors. If the first value is equal to the second value, it implies that there may be an error of about 10% between the first value and the second value. If the first direction is perpendicular or “substantially” perpendicular to the second direction, the angle between the first direction and the second direction may be between 80° and 100°. If the first direction is parallel or “substantially” parallel to the second direction, the angle between the first direction and the second direction may be between 0° and

In the specification and claims, unless otherwise specified, ordinal numbers, such as “first”, “second”, etc., used herein are intended to modify elements, which do not imply and represent that the (or these) elements have any previous ordinal numbers, nor does not imply an order of one element over another, or an order in manufacturing methods. These ordinal numbers are used only to clearly distinguish an element with a certain designation from another element with the same designation. The claims and the description may not use the same term, accordingly, the first component in the description may be the second component in the claim.

In addition, the electronic device of the present disclosure may include a display device, a backlight device, an antenna device, a sensing device, a tiled device, a touch display, a curved display, or a non-rectangular electronic device (free shape display), but the present disclosure is not limited thereto. The electronic device may include, for example, liquid crystals, light emitting diodes, fluorescence molecules, phosphors, other suitable display media, or combinations thereof, but the present disclosure is not limited thereto. The display device may be a non-self-luminous display device or a self-luminous display device; the antenna device may be a liquid crystal antenna device or a non-liquid crystal antenna device; and the sensing device may be a sensing device for sensing capacitance, light, thermal energy or ultrasonic waves; but the present disclosure is not limited thereto. The electronic components included in the electronic device may include passive components and active components, such as capacitors, resistors, inductors, diodes, transistors, and the like. The diode may include a light emitting diode (LED) or a photodiode. The light emitting diode may, for example, include an organic light emitting diode (OLED), a mini light emitting diode (mini LED), a micro light emitting diode (micro LED) or a quantum dot light emitting diode (quantum dot LED), but the present disclosure not limited thereto. The tiled device may be, for example, a tiled display device or a tiled antenna device, but the present disclosure is not limited thereto. It should be noted that the electronic device may be any arrangement and combination of the aforementioned electronic device, but the present disclosure is not limited thereto. In addition, the electronic device may be a bendable or flexible electronic device. It should be noted that the electronic device may be any arrangement and combination of the aforementioned electronic device, but the present disclosure is not limited thereto. In addition, the shape of the electronic device may be rectangular, circular, polygonal, with curved edges, or other suitable shapes. The electronic device may have peripheral systems such as a drive system, a control system, a light source system, a shelf system, etc. to support a display device, an antenna device or a tiled device. For the convenience of description, the electronic device is the display device for description below, but the present disclosure is not limited thereto.

It should be understood that, according to the embodiments of the present disclosure, an optical microscope (OM), a scanning electron microscope (SEM), a film thickness profilometer (α-step), an ellipsometer, or other suitable methods may be used to measure the depth, thickness, width or height of each component, or the spacing or distance between components. According to some embodiments, a scanning electron microscope can be used to obtain a cross-sectional structure image including the components to be measured, and measure the depth, thickness, width or height of each component, or the spacing or distance between components.

It should be noted that in the following embodiments, without departing from the spirit of the present disclosure, features in several different embodiments may be replaced, reorganized, and mixed to complete other embodiments. As long as the features of the various embodiments do not violate the spirit of the invention or conflict, they can be mixed and matched arbitrarily.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

FIG. 1 is a schematic view showing a method for manufacturing an electronic device according to one embodiment of the present disclosure.

As shown in FIG. 1, a first substrate 10 is firstly provided. In the present disclosure, the material of the first substrate 10 may include quartz, glass, silicon wafer, sapphire, polycarbonate (PC), polyimide (PI), polypropylene (PP), polyethylene terephthalate (PET) or other plastic or polymer materials, or a combination thereof, but the present disclosure is not limited thereto.

Next, an insulating layer 11 is formed on the first substrate 10, followed by patterning the insulating layer 11 to make the insulating layer has a first opening 111. In some embodiments, the insulating layer 11 may include silicon oxide, silicon nitride, silicon oxynitride, or a combination thereof, but the present disclosure is not limited thereto. In the present disclosure, any suitable method may be used to pattern the insulating layer 11, including photolithography and etching, and the etching may include dry etching or wet etching, but the present disclosure is not limited thereto. In the present disclosure, the thickness of the insulating layer 11 may be at least 500 Å, but the present disclosure is not limited thereto. In some embodiments, a part of the first substrate 10 may be exposed from the first opening 111 of the insulating layer 11 in the normal direction Z of the first substrate 10, but the present disclosure is not limited thereto. When other material layers are included between the insulating layer 11 and the first substrate 10, the first opening 111 may not expose the first substrate 10, but expose other material layers below.

Then, a conductive layer 12 is formed on the insulating layer 11, followed by patterning the conductive layer 12 to form a plurality of first electrodes 121. Herein, there is a first spacing area P1 between two adjacent first electrodes 121 of the plurality of first electrodes 121, and the first spacing area P1 and the first opening 111 may be overlapped in the normal direction Z of the first substrate 10. In other words, in the normal direction Z of the first substrate 10, a projection of the first spacing area P1 on the first substrate 10 and a projection of the first opening 111 on the first substrate 10 may be overlapped. In some embodiments, the material of the conductive layer 12 may include indium tin oxide (ITO), aluminum zinc oxide (AZO), indium gallium zinc oxide (IGZO), antimony tin oxide (ATO), fluorine-doped tin oxide (FTO), other suitable materials or combinations thereof, but the present disclosure is not limited thereto. In some embodiments, any suitable method may be used to pattern the conductive layer 12, including photolithography and etching, and the etching may include dry etching or wet etching, but the present disclosure is not limited thereto. In some embodiments, the thickness of the conductive layer 12 may be greater than 300 Å and less than or equal to 2000 Å, for example, may be greater than or equal to 420 Å, greater than or equal to 850 Å, greater than or equal to 1100 Å or greater than or equal to 1500 Å; but the present disclosure is not limited thereto. By increasing the thickness of the conductive layer 12, the obtained first electrodes 121 can have lower resistance.

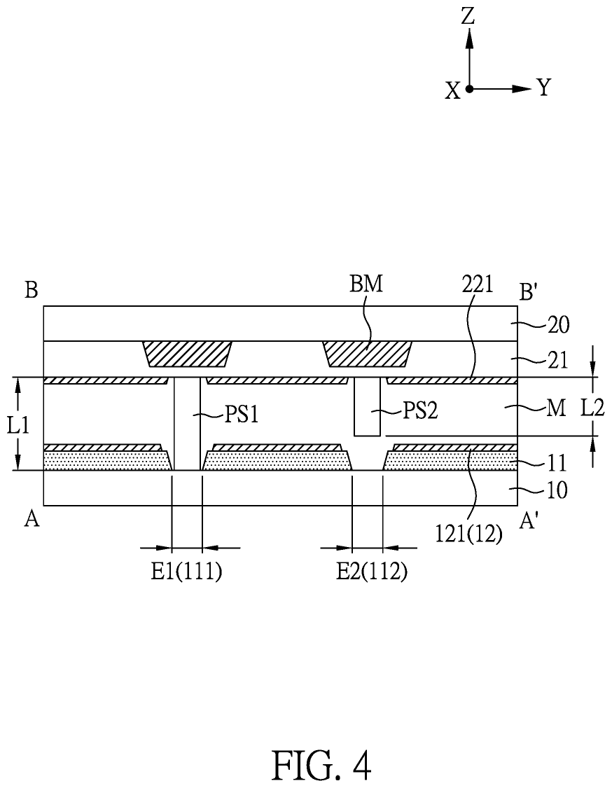

Then, even not shown in the figure, a second substrate is provided and assembled with the first substrate 10 to obtain the electronic device of the present disclosure. Herein, a medium layer (such as the medium layer M in FIG. 4) may be included between the first substrate 10 and the second substrate. The medium layer M includes, for example, a display medium layer for displaying various images, but the present disclosure is not limited thereto. In some embodiments, the material of the medium layer may include guest host type liquid crystals (GHLCs), dye liquid crystals, twisted nematic liquid crystals (TN LCs), super twisted nematic liquid crystals (STN LCs), polymer dispersed liquid crystals (PDLCs), polymer network liquid crystals (PNLCs), cholesteric liquid crystals, polymer-stabilized cholesterol texture liquid crystals (PSCT LCs), suspended particle materials (SPD), electrochromic materials, etc., other suitable materials or combinations thereof, but the present disclosure is not limited thereto.

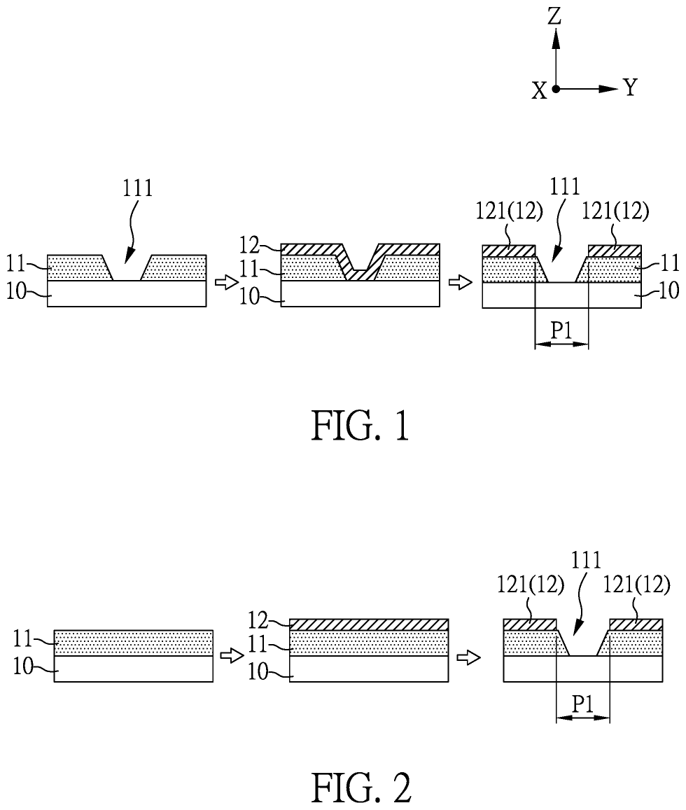

FIG. 2 is a schematic view showing a method for manufacturing an electronic device according to one embodiment of the present disclosure.

As shown in FIG. 2, a first substrate 10 is firstly provided. Next, an insulating layer 11 is formed on the first substrate 10, followed by forming a conductive layer 12 on the insulating layer 11. Then, the conductive layer 12 is patterned to form a plurality of first electrodes 121, followed by patterning the insulating layer 11 to make the insulating layer 11 has a first opening 111. Herein, there is a first spacing area P1 between two adjacent first electrodes 121 of the plurality of first electrodes 121, and the first spacing area P1 and the first opening 111 may be overlapped in the normal direction Z of the first substrate 10. In other words, in the normal direction Z of the first substrate 10, a projection of the first spacing area P1 on the first substrate 10 and a projection of the first opening 111 on the first substrate 10 may be overlapped. Then, even not shown in the figure, a second substrate is provided and assembled with the first substrate 10 to obtain the electronic device of the present disclosure. Herein, a medium layer (such as the medium layer M in FIG. 4) may be included between the first substrate 10 and the second substrate. The material of the medium layer M is similar to that described above, and are not described again.

In the present disclosure, the materials of the first substrate 10, the insulating layer 11, the conductive layer 12 and the medium layer M are similar to those described above, and are not described again. In addition, any suitable method may be used to pattern the insulating layer 11 and the conductive layer 12, and the suitable methods are similar to those described above and are not described again.

Thus, the method for manufacturing the electronic device of the present disclosure may comprise the following steps: providing a first substrate 10; forming an insulating layer 11 on the first substrate 10; forming a conductive layer 12 on the insulating layer 11; patterning the insulating layer 11 and the conductive layer 12 respectively to make the insulating layer 11 have a first opening 111 and make the conductive layer 12 form a plurality of first electrodes 121. Herein, there is a first spacing area P1 between two adjacent first electrodes 121 of the plurality of first electrodes 121, and the first spacing area P1 and the first opening 111 are overlapped in the normal direction Z of the first substrate 10. Through the method of the present disclosure, the problem of etching residue of the conductive layer 12 can be improved, and the risk of short circuit between adjacent first electrodes 121 can be reduced.

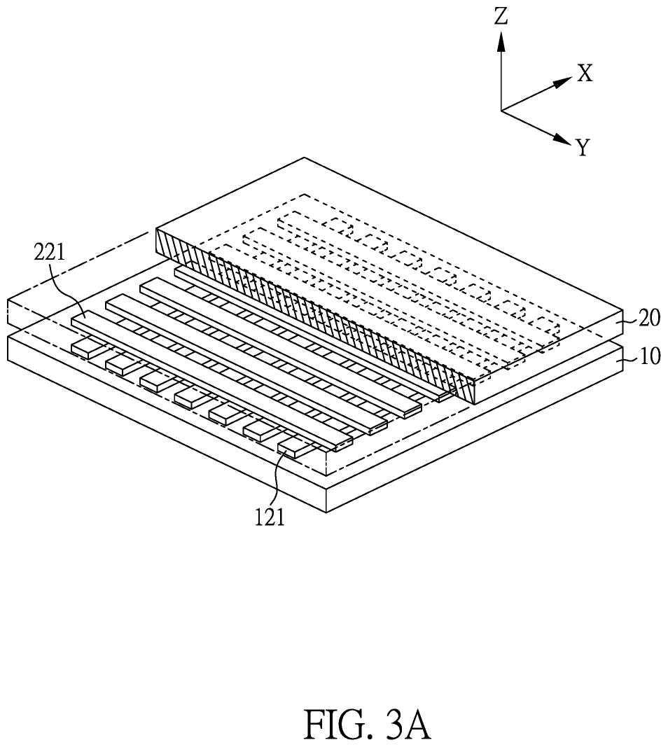

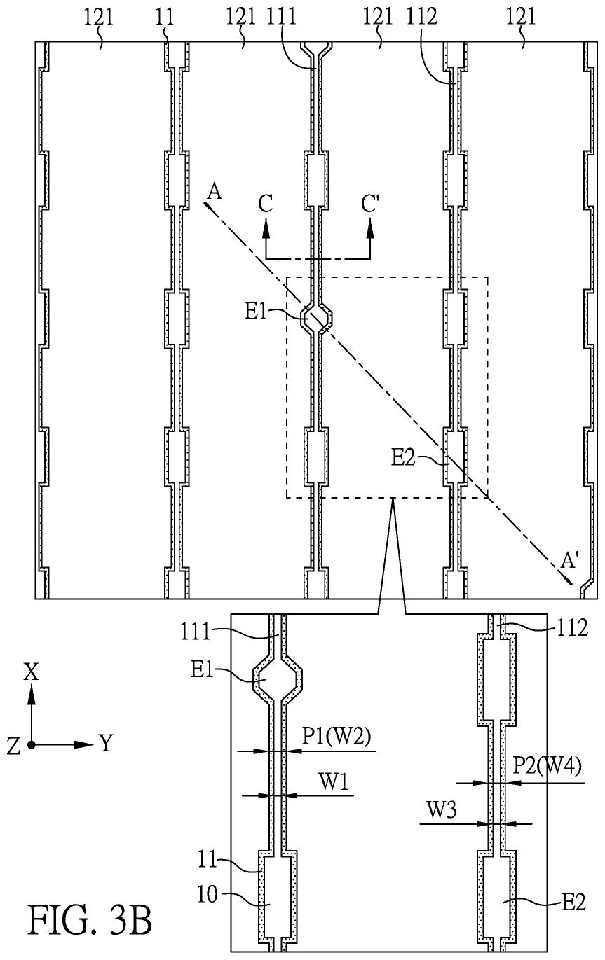

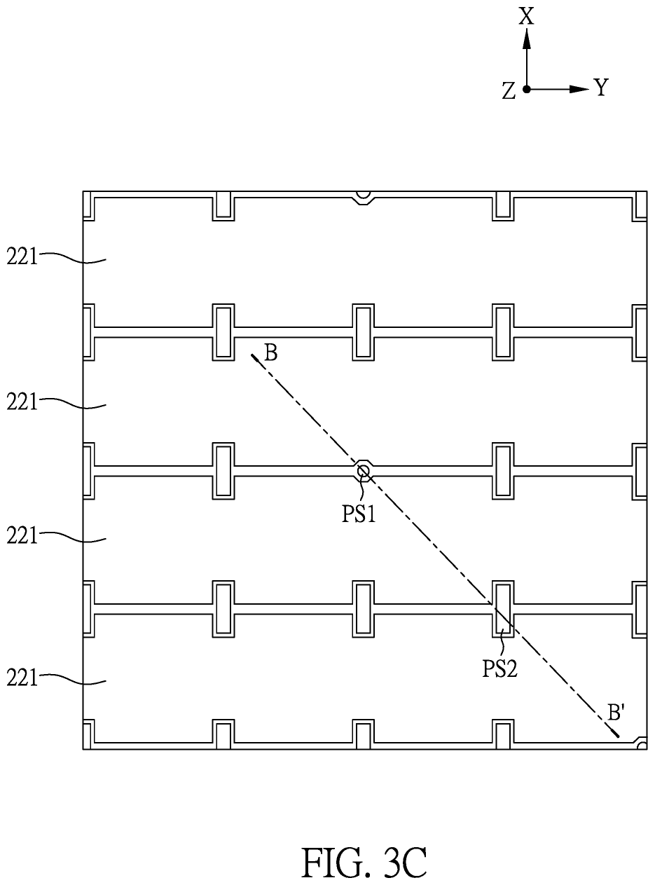

FIG. 3A is a three-dimensional schematic view of a part of an electronic device according to one embodiment of the present disclosure. FIG. 3B is a top view showing a part of a first substrate according to one embodiment of the present disclosure. FIG. 3C is a bottom view showing a part of a second substrate according to one embodiment of the present disclosure. FIG. 4 is a cross-sectional view of a part of an electronic device according to one embodiment of the present disclosure. FIG. 4 is a cross-sectional view combining the cross-section of FIG. 3B along the A-A′ line and the cross-section of FIG. 3C along the B-B′ line. In addition, for the convenience of description, some components are not shown in the figures, for example, the components such as the light shielding layer, the insulating layer, the first spacer, and the second spacer are not shown in FIG. 3A.

As shown in FIG. 3A and FIG. 4, the electronic device of the present disclosure may comprise: a first substrate 10; a second substrate 20 disposed opposite to the first substrate 10; a plurality of first electrodes 121 disposed on the first substrate 10; a plurality of second electrodes 221 disposed on the second substrate 20; and a first spacer PS1 disposed between the first substrate 10 and the second substrate 20. In the present disclosure, the plurality of first electrodes 121 may be arranged along a first direction Y, and the plurality of first electrodes 121 may extend along a second direction X. In the present disclosure, the plurality of second electrodes 221 may be arranged along the second direction X, and the plurality of second electrodes 221 may extend along the first direction Y. The first direction Y is different from the second direction X. In some embodiments, the first direction Y is substantially perpendicular to the second direction X. In some embodiments, in the normal direction Z of the first substrate 10, the plurality of first electrodes 121 and the plurality of second electrodes 221 may cross, and the first electrodes 121 and the second electrodes 221 are partially overlapped. More specifically, the electronic device comprises a plurality of pixels, and the area of the pixels may be defined by the overlapping areas of the first electrodes 121 and the second electrodes 221. By applying voltages to the first electrodes 121 and the second electrodes 221 respectively, the modulation of the medium layer M disposed between the first substrate 10 and the second substrate 20 can be controlled. When the electronic device is a display device, by applying voltages to the first electrodes 121 and the second electrodes 221 respectively, the modulation of the arrangement of the medium layer M disposed between the first substrate 10 and the second substrate 20 can be controlled to display various images. In some embodiments, the material of the second substrate 20 is similar to that of the first substrate 10, and the material of the second electrodes 221 is similar to that of the first electrodes 121, which are not described again. In some embodiments, the shape of the first spacer PS1 is not particularly limited, for example, it may be a cylinder, a rectangular cylinder, a trapezoidal cylinder, a triangular cylinder, a cone, a triangular pyramid or other irregular cylinders, but the present disclosure is not limited thereto. In addition, in one embodiment of the present disclosure, as shown in FIG. 4, the first spacer PS1 may be in contact with the first substrate 10.

As shown in FIG. 3B, FIG. 3C and FIG. 4, in the present disclosure, the electronic device further comprises an insulating layer 11 disposed between the first substrate 10 and the plurality of first electrodes 121. The insulating layer 11 has a first opening 111, the first opening 111 extends along the second direction X and comprises a first enlarged part E1, and the first enlarged part E1 and the first spacer PS1 are overlapped in the normal direction Z of the first substrate 10. When the thickness of the first electrodes 121 increases, the problem of the etching residue of the material of the first electrodes 121 can be improved by forming the first opening 111. Thus, the risk of short circuit between the first electrodes 121 can be reduced or the yield of electronic devices can be improved.

As shown in FIG. 3B, the plurality of first electrodes 121 are arranged along the first direction Y, there is a first spacing area P1 between two adjacent first electrodes 121 of the plurality of first electrodes 121, and the first spacing area P1 may extend along the second direction X. Herein, the first spacing area P1 and the first opening 111 are overlapped in the normal direction Z of the first substrate 10. In other words, a projection of the first spacing area P1 on the first substrate 10 and a projection of the first opening 111 on the first substrate 10 may be overlapped. In one embodiment, a width W2 of the first spacing area P1 is greater than a width W1 of the first opening 111 in the first direction Y. Thus, in the normal direction Z of the first substrate 10, the first electrodes 121 and the insulating layer 11 are exposed at the same time. In some embodiments, the width W1 of the first opening 111 may range from 1.5 μm to 120 μm, but the present disclosure is not limited thereto. In some embodiments, the width W1 of the first opening 111 may range from 2 μm to 50 μm. The “width of the first spacing area” refers to the minimum width between two adjacent first electrodes 121 in the first direction Y. The “width of the first opening” refers to the width of the opening of the insulating layer 11 in the first direction Y that the underlying material layer is exposed therefrom, for example, the width W1 of the first opening 111 of the insulating layer 11 that the underlying first substrate 10 is exposed therefrom. In one embodiment of the present disclosure, in the normal direction Z of the first substrate 10, the material layer under the insulating layer 11 may be exposed from the first opening 111, for example, a part of the first substrate 10 is exposed therefrom, but the present disclosure is not limited thereto.

In addition, in the present disclosure, the shape of the first enlarged part E1 is not particularly limited, and the shape of the first enlarged part E1 may selectively match the design of the first spacer PS1. As shown in FIG. 3B, in the normal direction Z of the first substrate 10, the first enlarged part E1 may have a hexagonal shape, but the present disclosure is not limited thereto. For example, the first enlarged part E1 may have a rectangular, trapezoidal, prismatic, curved, or irregular shape. In some embodiments, the projection of the first enlarged part E1 on the first substrate 10 may be larger than the projection of the first spacer PS1 on the first substrate 10. In other words, the projection of the first spacer PS1 on the first substrate 10 may be located within the projection of the first enlarged part E1 on the first substrate 10.

As shown in FIG. 3B, there is a second spacing area P2 between two adjacent first electrodes 121 of the plurality of first electrodes 121, and the insulating layer 11 may has a second opening 112. Herein, the second spacing area P2 and the second opening 112 may respectively extend along the second direction X, and the second spacing area P2 and the second opening 112 are overlapped in the normal direction Z of the first substrate 10. In other words, the projection of the second spacing area P2 on the first substrate 10 and the projection of the second opening 112 on the first substrate 10 may be overlapped. In some embodiments, the width W4 of the second spacing area P2 may be greater than the width W3 of the second opening 112. In some embodiments, the width W4 of the second spacing area P2 may be similar to the width W2 of the first spacing area P1, and is not described again. In some embodiments, the width W3 of the second opening 112 may be similar to the width W1 of the first opening 111, and is not described again. Thus, in one embodiment of the present disclosure, in the normal direction Z of the first substrate 10, the material layer under the insulating layer 11 may be exposed from the second opening 112, for example, a part of the first substrate 10 is exposed from the second opening 112.

As shown in FIG. 3B, FIG. 3C and FIG. 4, the electronic device of the present disclosure may further comprise a second spacer PS2 disposed between the first substrate 10 and second substrate 20, wherein the insulating layer 11 has a second opening 112, the second opening 112 comprises a second enlarged part E2, the second enlarged part E2 and the second spacer PS2 are overlapped in the normal direction Z of the first substrate 10, and a size of the first enlarged part E1 is different from a size of the second enlarged part E2. Herein, the “sizes of the enlarged parts are different” means that the shapes or sizes of the enlarged parts are different, more specifically, the shapes or areas of the enlarged parts projected on the first substrate 10 are different. In some embodiments, as shown in FIG. 3B, the second enlarged part E2 has a rectangular shape, but the present disclosure is not limited thereto. For example, the second enlarged part E2 may also have a rectangular, trapezoidal, prism, arc, or irregular shape. In the present disclosure, the size of the first spacer PS1 may be different from or the same as the size of the second spacer PS2. The “sizes of the spacers are different” means that the shapes or sizes of the spacers are different, and more specifically, the shapes or areas of the projections of the spacers on the first substrate 10 are different. In some embodiments, the shape of the second spacer PS2 is not particularly limited, for example, it can be a rectangular cylinder, a cylinder, a trapezoidal cylinder, a triangular cylinder, a cone, a triangular pyramid, or other irregular cylinders, but the present disclosure is not limited to this. In some embodiments, as shown in FIG. 4, the height L1 of the first spacer PS1 is greater than the height L2 of the second spacer PS2, and the second spacer PS2 may not be in contact with the first substrate 10.

In one embodiment of the present disclosure, as shown in FIG. 3B and FIG. 3C, a plurality of second spacers PS2 may be respectively disposed around the first spacer PS1, but the present disclosure is not limited thereto. In other words, a plurality of second enlarged parts E2 may be respectively disposed around the first enlarged part E1, but the present disclosure is not limited thereto. In other embodiments (not shown in the figure), the first spacers PS1 and the second spacers PS2 may be alternately arranged, and similarly, the first enlarged parts E1 and the second enlarged parts E2 may also be alternately arranged.

In the present disclosure, as shown in FIG. 4, the electronic device may further comprise a light shielding unit BM disposed between the first substrate 10 and the second substrate 20, wherein the first opening 111 (or the first spacing area P1) and the light shielding unit BM are overlapped in the normal direction Z of the first substrate 10. Since the medium layer M (such as a liquid crystal layer) overlapping the first opening 111 (or first spacing area P1) cannot be adjusted according to the drive of the first electrode 121 or the second electrode 221, the first opening 111 (or the first spacing area P1) and the light shielding unit BM are overlapped in the normal direction Z of the first substrate 10, which can reduce light leakage and affect the display quality. Similarly, the second opening 112 (or the second spacing area P2) and the light shielding unit BM are overlapped in the normal direction Z of the first substrate 10, and its advantages are as described above. In some embodiments, the first electrode 121 or the second electrode 221 can be overlapped with the light shielding unit BM, which can reduce light leakage and improve display quality. It should be noted that the above overlapping of two components means that the two components may completely overlap or at least partially overlap. In some embodiments, the projection area where the first opening 111 (or the first spacing area P1) is projected on the first substrate 10 is, for example, located within the projection area where the light shielding unit BM is projected on the first substrate 10. In some embodiments, the projection area where the second opening 112 (or the second spacing area P2) is projected on the first substrate 10 is located within the projection area where the light shielding unit BM is projected on the first substrate 10. In the present disclosure, as shown in FIG. 4, the electronic device may further include a planarization layer 21 disposed between the second substrate 20 and the second electrodes 221, but the present disclosure is not limited thereto. In other embodiments (not shown), another insulating layer (not shown) or filter layer (not shown) may be selectively disposed between the second substrate 20 and the second electrodes 221. In some embodiments, the first spacer PS1 and the second spacer PS2 may be in contact with the planarization layer 21 respectively. In one embodiment, the material of the planarization layer 21 may include silicon oxide, silicon nitride, silicon oxynitride, aluminum oxide, resin, polymer, photoresist or a combination thereof, but the present disclosure is not limited thereto.

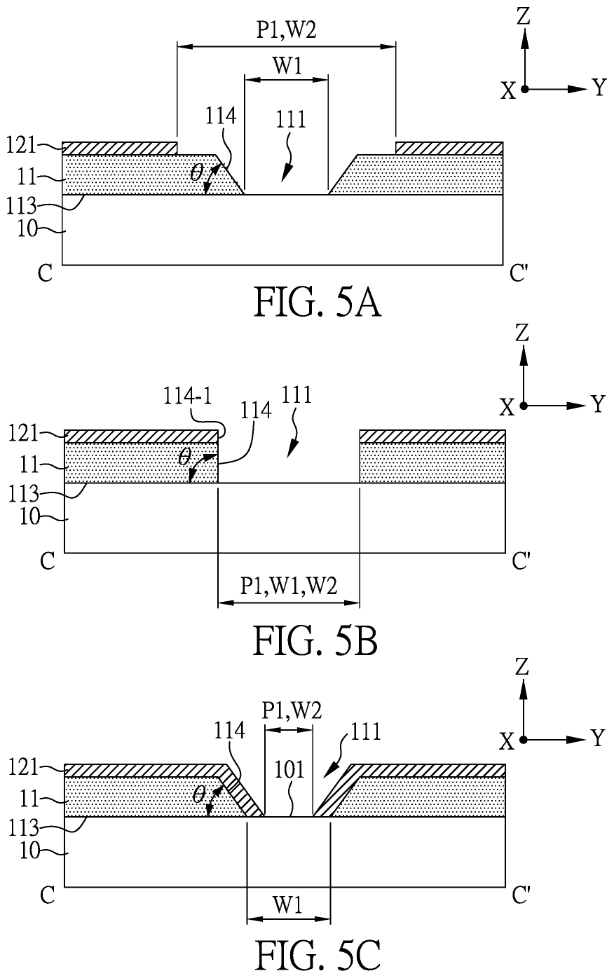

FIG. 5A to FIG. 5C are cross-sectional views of a part of an electronic device according to different embodiments of the present disclosure. FIG. 5A to FIG. 5C are cross-sectional views of the cross-section of FIG. 3B along the C-C′ line.

In one embodiment of the present disclosure, as shown in FIG. 5A, in a cross-sectional view, the width W2 of the first spacing area P1 may be greater than the width W1 of the first opening 111. Herein, in a cross-sectional view, the insulating layer 11 has a bottom surface 113 and a side surface 114, the side surface 114 is adjacent to the first opening 11, and an included angle θ between the bottom surface 113 and the side surface 114 may be an acute angle. More specifically, the included angle θ between the bottom surface 113 and the side surface 114 of the insulating layer 11 may range from 35° to 65°, but the present disclosure is not limited thereto. In some embodiments, the included angle θ may range from 40° to 60°. In some embodiments, the included angle θ may range from 45° to 55°.

In one embodiment of the present disclosure, as shown in FIG. 5B, in a cross-sectional view, the width W2 of the first spacing area P1 may be substantially the same as the width W1 of the first opening 111. Herein, an included angle θ between the bottom surface 113 and the side surface 114 of the insulating layer 11 corresponding to the first opening 111 may be substantially a right angle. More specifically, the included angle θ between the bottom surface 113 and the side surface 114 of the insulating layer 11 corresponding to the first opening 111 may be about 90°. In other embodiments (not shown), the side surface 114 of the insulating layer 11 and the side surface 114-1 of the first electrode 121 corresponding to the first opening 111 may be aligned or not be aligned.

In one embodiment of the present disclosure, as shown in FIG. 5C, the first electrode 121 may be extended and disposed in a part of the first opening 111, for example, the first electrode 121 may cover at least a part of the side surface 114 of the insulating layer 11 and/or at least a part of the upper surface 101 of the first substrate 10, or the first electrode 121 may be in contact with at least a part of the side surface 114 of the insulating layer 11 and/or at least a part of the upper surface 101 of the first substrate 10. In some embodiments, in a cross-sectional view, the width W2 of the first spacing area P1 may be less than the width W1 of the first opening 111.

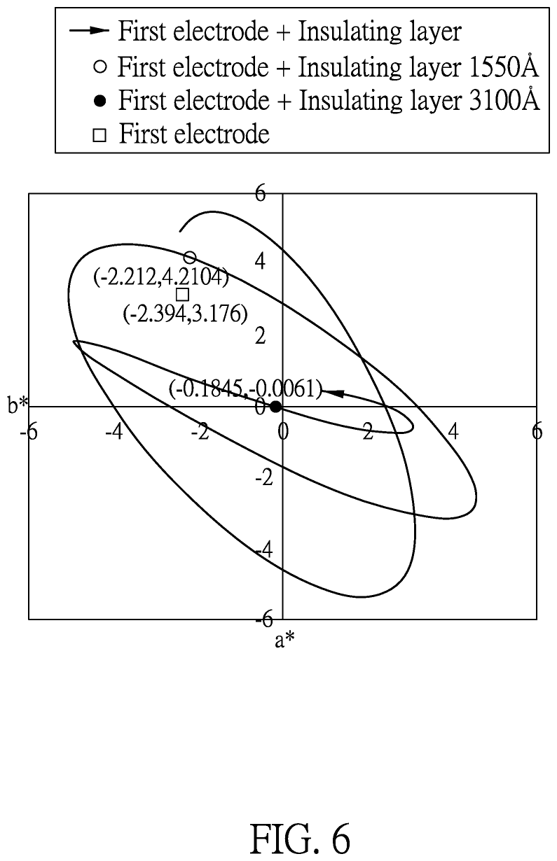

FIG. 6 is a chromaticity diagram according to one embodiment of the present disclosure.

The electronic device shown in FIG. 3B to FIG. 4 is used to measure the color coordinates thereof. For example, the thickness of the first electrode is fixed at 1500 Å, the thickness of the insulating layer is gradually increased from 50 Å, and the color shift of the electronic device is observed. Herein, the a* axis represents the red/green axis, the positive value of a represents the red shift, the negative value of a represents the green shift; and the b* axis represents the blue/yellow axis, the positive value of b represents the yellow shift, and the negative value of b represents a blue shift. As shown in FIG. 6, when the insulating layer is not included, the green and yellow offsets are observed. When the thickness of the insulating layer is 3100 Å, the color coordinate can be close to the origin, that is, the chromaticity is close to 0. When the thickness of the insulating layer is increased from 3100 Å, the color coordinates shift from the origin. It should be noted that FIG. 6 is only a diagram showing that the color coordinate can be close to the origin (that is, the chromaticity is close to 0) under some designs that the thickness of the first electrode is, for example, 1500 Å and the thickness of the insulating layer is 3100 Å. However, the chromaticity related to the designs of the thickness of the insulating layer is not limited to this, and the chromaticity coordinates may be changed by the material of the first electrode or the material of the insulating layer. FIG. 6 is only used to illustrate the situation that the color shift may be adjusted by modifying the thickness of the insulating layer.

The specific embodiments above should be interpreted as illustrative only, not limiting the rest of the present disclosure in any way, and the features of different embodiments can be mixed and matched as long as they do not conflict with each other.

Although the present disclosure has been explained in relation to its embodiment, it is to be understood that many other possible modifications and variations can be made without departing from the spirit and scope of the disclosure as hereinafter claimed.

1. An electronic device, comprising:
a first substrate;
a second substrate disposed opposite to the first substrate;
a plurality of first electrodes disposed on the first substrate;
an insulating layer disposed between the first substrate and the plurality of first electrodes; and
a first spacer disposed between the first substrate and the second substrate,
wherein the insulating layer has a first opening, the first opening comprises a first enlarged part, and the first enlarged part and the first spacer are overlapped in a normal direction of the first substrate.

2. The electronic device of claim 1, wherein the plurality of first electrodes are arranged along a first direction, and there is a first spacing area between two adjacent first electrodes of the plurality of first electrodes; wherein the first spacing area and the first opening are overlapped in the normal direction of the first substrate.

3. The electronic device of claim 2, wherein a width of the first spacing area is greater than a width of the first opening in the first direction.

4. The electronic device of claim 1, wherein the plurality of first electrodes are arranged along a first direction, and a width of the first opening ranges from 1.5 μm to 120 μm in the first direction.

5. The electronic device of claim 1, further comprising a second spacer disposed between the first substrate and second substrate, wherein the insulating layer has a second opening, the second opening comprises a second enlarged part, the second enlarged part and the second spacer are overlapped in the normal direction of the first substrate, and a size of the first enlarged part is different from a size of the second enlarged part.

6. The electronic device of claim 5, wherein a height of the first spacer is greater than a height of the second spacer.

7. The electronic device of claim 5, further comprising a light shielding unit disposed between the first substrate and the second substrate, wherein the second opening and the light shielding unit are overlapped in the normal direction of the first substrate.

8. The electronic device of claim 1, wherein a part of the first substrate is exposed from the first opening in the normal direction of the first substrate.

9. The electronic device of claim 1, wherein in a cross-sectional view, the insulating layer has a bottom surface and a side surface, the side surface is adjacent to the first opening, and an included angle between the bottom surface and the side surface ranges from 35° to 65°.

10. The electronic device of claim 1, further comprising a light shielding unit disposed between the first substrate and the second substrate, wherein the first opening and the light shielding unit are overlapped in the normal direction of the first substrate.

11. A method for manufacturing an electronic device, comprising the following steps:
providing a first substrate;
forming an insulating layer on the first substrate;
forming a conductive layer on the insulating layer;
patterning the insulating layer to make the insulating layer has a first opening; and
patterning the conductive layer to form a plurality of first electrodes,
wherein there is a first spacing area between two adjacent first electrodes of the plurality of first electrodes, and the first spacing area and the first opening are overlapped in a normal direction of the first substrate.

12. The method of claim 11, wherein the conductive layer is formed on the insulating layer after the insulating layer is patterned to make the insulating layer has the first opening.

13. The method of claim 11, wherein the insulating layer is patterned to make the insulating layer has the first opening after the conductive layer is formed on the insulating layer.

14. The method of claim 11, wherein the plurality of first electrodes are arranged along a first direction, and a width of the first spacing area is greater than a width of the first opening in the first direction.

15. The method of claim 11, wherein the plurality of first electrodes are arranged along a first direction, and a width of the first opening ranges from 1.5 μm to 120 μm in the first direction.

16. The method of claim 11, wherein a part of the first substrate is exposed from the first opening in the normal direction of the first substrate.

17. The method of claim 11, wherein in a cross-sectional view, the insulating layer has a bottom surface and a side surface, the side surface is adjacent to the first opening, and an included angle between the bottom surface and the side surface ranges from 35° to 65°.

18. The method of claim 11, further comprising a step of providing a second substrate and assembling the second substrate with the first substrate after the step of patterning the conductive layer to form the plurality of first electrodes, wherein a first spacer is disposed between the first substrate and the second substrate, the first opening comprises a first enlarged part, and the first enlarged part and the first spacer are overlapped in the normal direction of the first substrate.

19. The method of claim 18, wherein a second spacer is disposed between the first substrate and second substrate, wherein the insulating layer has a second opening, the second opening comprises a second enlarged part, the second enlarged part and the second spacer are overlapped in the normal direction of the first substrate, and a size of the first enlarged part is different from a size of the second enlarged part.

20. The method of claim 18, wherein a light shielding unit is disposed between the first substrate and the second substrate, and the first opening and the light shielding unit are overlapped in the normal direction of the first substrate.
